(19) United States
(12) Patent Application Publication
(10) Pub. No.: US 2025/0364955 A1
(43) Pub. Date: Nov. 27, 2025

(54) SEMICONDUCTOR DEVICE AND OPERATING METHOD THEREOF

(71) Applicants: TAIWAN SEMICONDUCTOR MANUFACTURING COMPANY, LTD., Hsinchu (TW); NATIONAL CHENG KUNG UNIVERSITY, Tainan City (TW)

(72) Inventors: Kuang-Wei Cheng, Tainan City (TW); Sin WANG, Taichung City (TW)

(73) Assignees: TAIWAN SEMICONDUCTOR MANUFACTURING COMPANY, LTD., Hsinchu (TW); NATIONAL CHENG KUNG UNIVERSITY, Tainan City (TW)

(21) Appl. No.: 18/671,348

(22) Filed: May 22, 2024

(51) Int. Cl. H03F 1/22

(52) U.S. Cl. CPC H03F 1/223; H03F 2200/294; H03F 2200/534; H03F 2200/541

(57) ABSTRACT

A semiconductor device includes a first transistor, a second transistor, a first inductor and a second inductor. A control terminal of the first transistor is configured to receive an input signal. The second transistor is coupled in series with the first transistor, a first terminal of the second transistor being configured to receive the input signal at a first node. The first inductor is coupled between first transistor and the first node. The second inductor is coupled to a control terminal of the second transistor. The first inductor and the second inductor are mutually coupled to each other with transformer coupling.

### BACKGROUND

In the design of radio frequency circuits, the front-end circuit of the radio frequency (RF) receiver, known as the “Low Noise Amplifier” (LNA), plays an essential role. In current applications, LNAs often require differential signals to provide better noise immunity and larger output swing. To convert a signal into a differential form, a balanced-to-unbalanced transformer (balun) is needed to achieve a one-to-two transformation. However, the drawback of using a balun is the inherent loss, which consequently reduces the overall noise figure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a semiconductor device in accordance with some embodiments of the present disclosure.

FIG. 2 is a schematic diagram of a semiconductor device corresponding to the semiconductor device shown in FIG. 1, in accordance with some embodiments of the present disclosure.

FIG. 3A is a schematic diagram of a semiconductor device corresponding to the semiconductor device shown in FIG. 2, in accordance with some embodiments of the present disclosure.

FIG. 3B is a schematic diagram of a part of the semiconductor device shown in FIG. 3A corresponding to a transformer coupling common source (TC-CS) path CSP, in accordance with some embodiments of the present disclosure.

FIG. 3C is a schematic diagram of a part of the semiconductor device shown in FIG. 3A corresponding to a transformer coupling common gate (TC-CG) path CGP, in accordance with some embodiments of the present disclosure.

FIG. 4 is a layout diagram of an input transformer corresponding to the inductors shown in FIG. 3A, in accordance with some embodiments of the present disclosure.

FIG. 5 is a layout diagram of an output transformer corresponding to the inductors shown in FIG. 3A, in accordance with some embodiments of the present disclosure.

FIG. 6 is a flowchart diagram of a method corresponding to the semiconductor devices shown in FIG. 1 to FIG. 3A, in accordance with some embodiments of the present disclosure.

FIG. 7 is a schematic view of a system for designing and/or manufacturing of at least one of the semiconductor devices shown in FIG. 1 to FIG. 3A, in accordance with some embodiments of the present disclosure.

FIG. 8 is a block diagram of an integrated circuit (IC)/semiconductor device manufacturing system, and an IC manufacturing flow associated therewith, in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

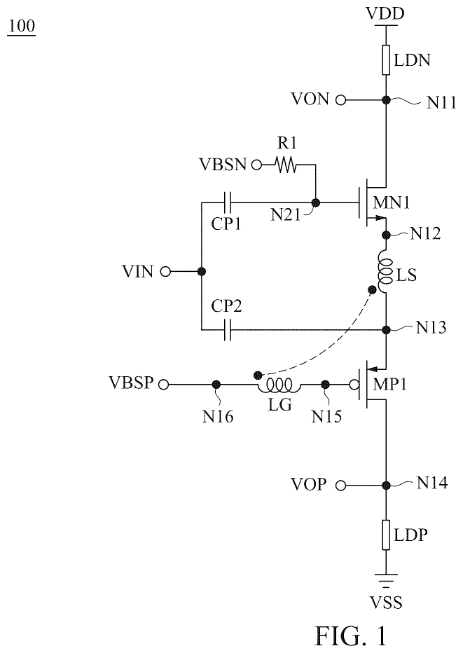

FIG. 1 is a schematic diagram of a semiconductor device 100 in accordance with some embodiments of the present disclosure. The semiconductor device 100 is configured to generate output signals VON and VOP according to an input signal VIN. In some embodiments, the input signal VIN is referred to as a single input signal, and the output signals VON and VOP are referred to as differential output signals. The semiconductor device 100 utilizes the single-to-differential architecture to reject common-mode noise and reduce even-order distortion, such that noises of the semiconductor device 100 are low. Accordingly, the semiconductor device 100 is referred to as a single-to-differential low noise amplifier.

As illustratively shown in FIG. 1, the semiconductor device 100 includes inductors LS, LG, capacitors CP1, CP2, loads LDN, LDP, a resistor R1 and transistors MN1, MP1. In some embodiments, conductive types of the transistors MN1 and MP1 are different from each other. For example, the transistors MN1 and MP1 are implemented by an N-type metal-oxide-semiconductor (MOS) transistor and a P-type MOS transistor, respectively.

As illustratively shown in FIG. 1, a terminal of the load LDN is configured to receive a reference voltage signal VDD, and another terminal of the load LDN is coupled to the transistor MN1 at a node N11. A terminal of the transistor MN1 is coupled to the load LDN at the node N11, another terminal of the transistor MN1 is coupled to the inductor LS at a node N12, and a control terminal of the transistor MN1 is coupled to the capacitor CP1 at a node N21. A terminal of the capacitor CP1 is coupled to the node N21, and another terminal of the capacitor CP1 is configured to receive the input signal VIN. A terminal of the load LDP is configured to receive a reference voltage signal VSS, and another terminal of the load LDN is coupled to the transistor MP1 at a node N14. A terminal of the transistor MP1 is coupled to the load LDN at the node N14, another terminal of the transistor MP1 is coupled to the inductor LS at a node N13, and a control terminal of the transistor MP1 is coupled to the inductor LG at a node N15. A terminal of the inductor LG is coupled to the node N15, and another terminal of the inductor LG is configured to receive a bias voltage signal VBSP at a node N16. A terminal of the capacitor CP2 is coupled to the node N13, and another terminal of the capacitor CP1 is configured to receive the input signal VIN. A terminal of the resistor R1 is coupled to the node N21, and another terminal of the resistor R1 is configured to receive a bias voltage signal VBSN.

In some embodiments, the reference voltage signal VDD has a power voltage level, and the reference voltage signal VSS has a ground voltage level. In some embodiments, a voltage level of the reference voltage signal VDD is larger than a voltage level of the reference voltage signal VSS.

In some embodiments, a voltage level of the bias voltage signal VBSN is smaller than the voltage level of the reference voltage signal VDD and is larger than a voltage level of the bias voltage signal VBSP, and a voltage level of the bias voltage signal VBSP is larger than the voltage level of the reference voltage signal VSS. In some embodiments, the bias voltage signals VBSN and VBSP are generated by a biasing circuit. It is noted that the biasing circuit is not shown in the figures.

In some embodiments, the inductors LG and LS are mutually coupled to each other with transformer coupling. Alternatively stated, a current signal flowing through the inductor LS induces a current signal flowing through the inductor LG. During operations, the semiconductor device 100 is configured to generate the current signal through the inductor LS and the transistors MN1, MP1 according to the input signal VIN. In some embodiments, the transformer coupling of the inductors LG and LS is referred to as input transformer coupling. The transformer corresponds to the inductors LG and LS is referred to as a center tapped transformer.

In some embodiments, regarding polarities of the inductors LG and LS, the nodes N13 and N16 have the same polarity, and the nodes N12 and N15 have the same polarity which is opposite to the polarity of the nodes N13 and N16. For example, when the node N13 has a positive polarity in response to the input signal VIN, the node N16 also has a positive polarity, and the node N15 has a negative polarity. In contrast, when the node N13 has a negative polarity in response to the input signal VIN, the node N16 also has a negative polarity, and the node N15 has a positive polarity. Accordingly, the inductors LG and LS are configured to increase a voltage difference between a gate terminal and a source terminal of the transistor MP1 (that is, the nodes N15 and N13), such that a transconductance of the semiconductor device 100 is boosted.

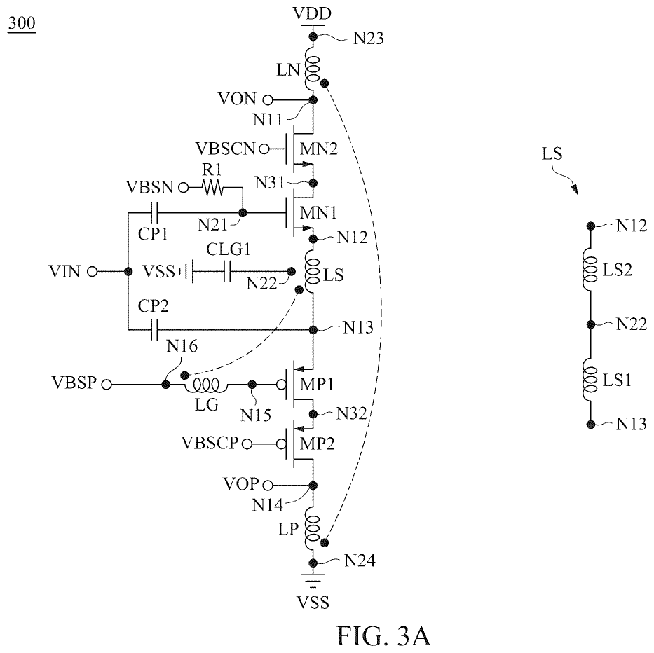

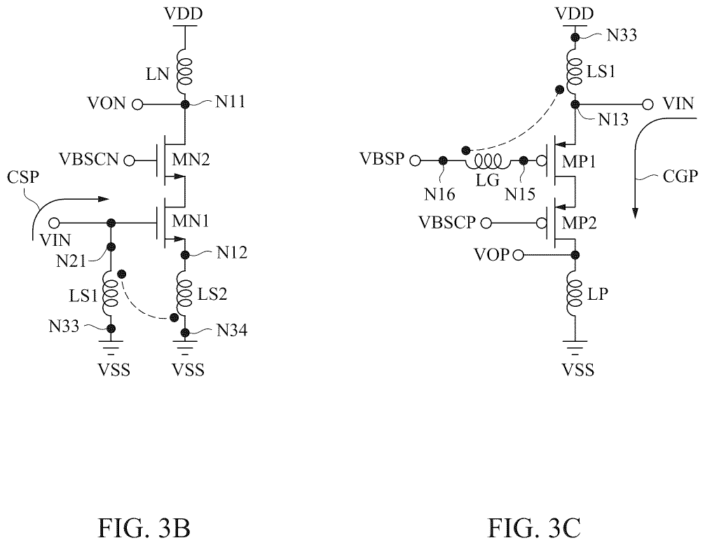

In some embodiments, the inductors LG, LS and transistors MN1, MP1 correspond to a common source (CS) amplifier and a common gate (CG) amplifier. The CS amplifier and the CG amplifier are stacked to share the direct current flowing through the inductor LS, such that the current efficiency is improved. Accordingly, the semiconductor device 100 is referred to as a current-reuse amplifier. Further details of the CS amplifier and the CG amplifier are described below with the embodiments associated with FIG. 3B and FIG. 3C.

In some approaches, an amplifier has a single-ended input-single-ended output structure, and includes no inductor. In such approaches, the common-mode noise cannot be eliminated, and the transconductance is not boosted.

Compared to above approaches, in some embodiments of present disclosure, the semiconductor device 100 has a single-ended input-differential output structure for reducing noises, and includes the inductors LS and LG for transconductance boosting. Furthermore, the current efficiency is improved by the current-reuse structure.

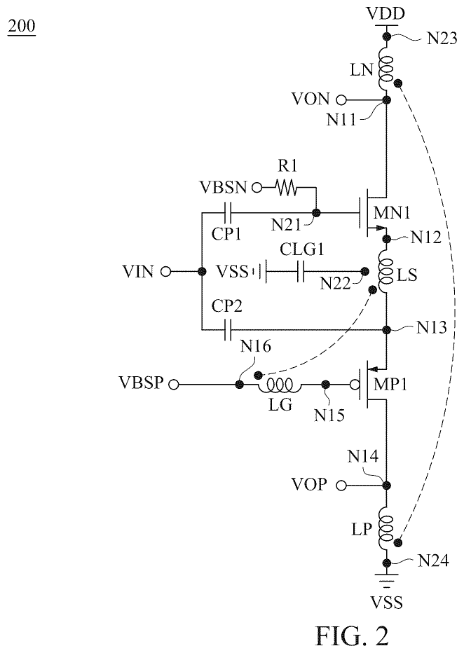

FIG. 2 is a schematic diagram of a semiconductor device 200 corresponding to the semiconductor device 100 shown in FIG. 1, in accordance with some embodiments of the present disclosure. Referring to FIG. 2 and FIG. 1, the semiconductor device 200 is an alternative embodiment of the semiconductor device 100. FIG. 2 follows a similar labeling convention to that of FIG. 1. For brevity, the discussion will focus more on differences between FIG. 2 and FIG. 1 than on similarities. Comparing to the semiconductor device 100, the semiconductor device 200 includes inductors LN and LP instead of the loads LDN and LDP.

As illustratively shown in FIG. 2, a terminal of the inductor LN is coupled to the node N11, and another terminal of the inductor LN is configured to receive the reference voltage signal VDD at a node N23. A terminal of the inductor LP is coupled to the node N14, and another terminal of the inductor LP is configured to receive the reference voltage signal VSS at a node N24. A terminal of the capacitor CP1 is coupled to the control terminal of the transistor MN1 at a node N21, and another terminal of the capacitor CP1 is configured to receive the input signal VIN. A terminal of the capacitor CP2 is coupled to the node N13, and another terminal of the capacitor CP2 is configured to receive the input signal VIN. A terminal of the capacitor CLG1 is coupled to the inductor LS at a node N22, and another terminal of the capacitor CLG1 is configured to receive the reference voltage signal VSS.

In some embodiments, the resistor R1 is configured to provide a bias voltage signal VBSN to the node N21. The resistor R2 is configured to provide a bias voltage signal VBSP to the node N16. Each of the capacitors CP1, CP2 and CLG1 is configured to filer direct current parts of the signals.

In some embodiments, the inductors LN and LP are mutually coupled to each other with transformer coupling. Alternatively stated, a current signal flowing through one of the inductors LN and LP induces a current signal flowing through another one of the inductors LN and LP.

In some embodiments, regarding polarities of the inductors LN and LP, the nodes N11 and N24 have the same polarity, and the nodes N14 and N23 have the same polarity which is opposite to the polarity of the nodes N11 and N24. For example, when the node N11 has a positive polarity in response to the output signal VON, the node N24 also has a positive polarity, and the nodes N14 and N23 have a negative polarity. In contrast, when the node N11 has a negative polarity in response to the output signal VON, the node N24 also has a negative polarity, and the nodes N14 and N23 have a positive polarity.

During operations, the inductors LN and LP are mutually coupled to boost a voltage gain of the semiconductor device 200 and improve the balance of the differential output signals VON and VOP. In some embodiments, the transformer coupling of the inductors LN and LP is referred to as output transformer coupling.

In some approaches, an amplifier includes no inductor at output terminals. In such approaches, the balance of the differential output is poor, such that a gain difference (Δgain) of the amplifier is larger, and a phase difference (Δphase) of the amplifier is far from 180 degrees.

Compared to above approaches, in some embodiments of present disclosure, the semiconductor device 200 includes the inductors LN and LP to improve the balance of the differential output. As a result, a gain difference of the semiconductor device 200 is small, and a phase difference is close to 180 degrees. Furthermore, the gain of the semiconductor device is increased.

In some embodiments, a ratio between inductances of the inductors LS and LG is 2:1. A ratio between inductances of the inductors LP and LN is 1:1. However, the embodiments of present disclosure are not limited to this. In various embodiments, various ratios between the inductors are contemplated as being within the scope of the present disclosure.

FIG. 3A is a schematic diagram of a semiconductor device 300 corresponding to the semiconductor device 200 shown in FIG. 2, in accordance with some embodiments of the present disclosure. Referring to FIG. 2 and FIG. 3A, the semiconductor device 300 is an alternative embodiment of the semiconductor device 300. FIG. 3A follows a similar labeling convention to that of FIG. 2. For brevity, the discussion will focus more on differences between FIG. 2 and FIG. 3A than on similarities. Comparing to the semiconductor device 200, the semiconductor device 300 further includes transistors MP2 and MN2.

As illustratively shown in FIG. 3A, a terminal of the transistor MN2 is coupled to the inductor LN at the node N11, another terminal of the transistor MN2 is coupled to the transistor MN1 at a node N31, and a control terminal of the transistor MN2 is configured to receive a bias voltage signal VBSCN. A terminal of the transistor MP2 is coupled to the inductor LP at the node N14, another terminal of the transistor MP2 is coupled to the transistor MP1 at a node N32, and a control terminal of the transistor MP2 is configured to receive a bias voltage signal VBSCP.

In some embodiments, a voltage level of the bias voltage signal VBSCN is larger than the voltage level of the bias voltage signal VBSN and is smaller than the voltage level of the reference voltage signal VDD. A voltage level of the bias voltage signal VBSCP is smaller than the voltage level of the bias voltage signal VBSP and is larger than the voltage level of the reference voltage signal VSS. In some embodiments, the bias voltage signals VBSCN and VBSCP are generated by a biasing circuit. It is noted that the biasing circuit is not shown in the figures.

In some embodiments, the transistors MN1 and MN2 have the same conductive type, and the transistors MP1 and MP2 have the same conductive type. For example, the transistors MN1 and MN2 are implemented by N-type MOS transistors, and the transistors MP1 and MP2 are implemented by P-type MOS transistors.

In some embodiments, the transistors MN2 and MP2 are configured to act as cascoded (cascade to cathode) stage of the output signals VON and VOP. Specifically, the transistor MN2 is configured to isolate the transistor MN1 from the node N11, and the transistor MP2 is configured to isolate the transistor MP1 from the node N14. Accordingly, the semiconductor device 300 has a better isolation with higher output impedance.

As illustratively shown in FIG. 3A, in some embodiments, the inductor LS includes inductors LS2 and LS1. A terminal of the inductor LS2 is coupled to the node N12, and another terminal of the inductor LS2 is coupled to the node N22. A terminal of the inductor LS1 is coupled to the node N13, and another terminal of the inductor LS2 is coupled to the node N22.

FIG. 3B is a schematic diagram of a device of a transformer coupling common source (TC-CS) path CSP corresponding to a part of the semiconductor device 300 shown in FIG. 3A, in accordance with some embodiments of the present disclosure.

As illustratively shown in FIG. 3B, the inductor LS1 is configured to receive the reference voltage signal VSS at a node N33 and is coupled to the node N21 through the capacitors CP1 and CP2. The inductor LS2 is configured to receive the reference voltage signal VSS at a node N34. In some embodiments, the inductors LS2 and LS1 are mutually coupled to each other with transformer coupling.

In some embodiments, regarding polarities of the inductors LS2 and LS1, the nodes N21 and N34 have the same polarity, and the nodes N12 and N33 have the same polarity which is opposite to the polarity of the nodes N21 and N34. For example, when the node N21 has a positive polarity in response to the input signal VIN, the node N34 also has a positive polarity, and the nodes N12 and N33 have a negative polarity. In contrast, when the node N21 has a negative polarity in response to the input signal VIN, the node N34 also has a negative polarity, and the nodes N12 and N33 has a positive polarity.

During operation, when the input signal VIN is transmitted along the TC-CS path CSP, the input signal VIN generates a current signal flowing through the inductor LS2. At this moment, a reverse current signal flowing through the inductor LS1 is induced by the current signal flowing through the inductor LS2. Accordingly, transconductance enhancement effect is achieved.

FIG. 3C is a schematic diagram of a device of a transformer coupling common gate (TC-CG) path CGP corresponding to a part of the semiconductor device 300 shown in FIG. 3A, in accordance with some embodiments of the present disclosure.

As illustratively shown in FIG. 3C, the inductor LS1 is configured to receive the reference voltage signal VDD at the node N33 and receive the input signal VIN at the node N13. The inductor LG is configured to receive the bias voltage signal VBSCP at the node N16. In some embodiments, the inductors LS2 and LS1 are mutually coupled to each other with transformer coupling.

In some embodiments, regarding polarities of the inductors LG and LS1, the nodes N13 and N16 have the same polarity, and the nodes N15 and N33 have the same polarity which is opposite to the polarity of the nodes N13 and N16. For example, when the node N13 has a positive polarity in response to the input signal VIN, the node N16 also has a positive polarity, and the nodes N15 and N33 have a negative polarity. In contrast, when the node N13 has a negative polarity in response to the input signal VIN, the node N16 also has a negative polarity, and the nodes N15 and N33 has a positive polarity.

During operation, when the input signal VIN is transmitted along the TC-CG path CGP, the input signal VIN generates a current signal flowing through the inductor LS1. At this moment, a reverse current signal flowing through the inductor LG is induced by the current signal flowing through the inductor LS1. Accordingly, transconductance enhancement effect is achieved. Referring to FIG. 3A to FIG. 3C, in some embodiments, the semiconductor device 300 is formed by combining the devices shown in FIG. 3B and FIG. 3C.

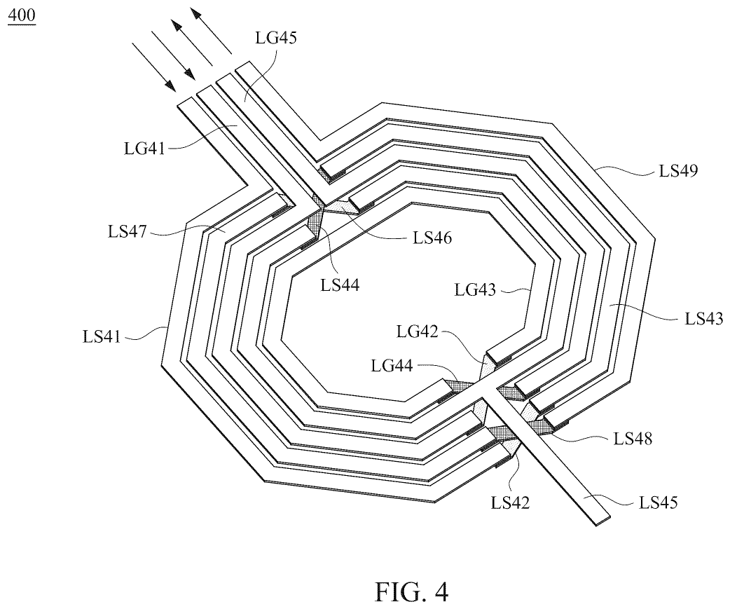

FIG. 4 is a layout diagram of an input transformer 400 corresponding to the inductors LS1, LS2 and LG shown in FIG. 3A, in accordance with some embodiments of the present disclosure. As illustratively shown in FIG. 4, the input transformer 400 includes inductor portions LS41-LS49 and LG41-LG49.

In some embodiments, the inductor portions LP54, LG42 and LS46 are disposed in the same layer. The inductor portions LS48, LG44 and LS44 are disposed in the same layer which is above the layer of the inductor portions LS42, LG42 and LS46. The inductor portions LS41, LS43, LS45, LS47, LS49, LG41, LG43 and LS45 are disposed in the same layer which is above the layer of the inductor portions LS42, LG42 and LS46.

As illustratively shown in FIG. 4, the inductor portion LS44 crosses over the inductor portion LS46. The inductor portion LG44 crosses over the inductor portion LG42. The inductor portion LS48 crosses over the inductor portion LS42. The inductor portion LS45 crosses over the inductor portions LS48 and LG44. The input transformer 400 has approximately a round shape. At one side of the round shape, the inductor portions LS47, LG41 and LS45 are arranged in order between the inductor portions LS41 and LG43. At another side of the round shape, the inductor portions LS43, LG45 and LS45 are arranged in order between the inductor portions LS49 and LG43.

In some embodiments, the inductor portions LS41 and LS43 are coupled to two terminals of the inductor portion LS42, respectively. The inductor portions LS43 and LS45 are coupled to two terminals of the inductor portion LS44, respectively. The inductor portions LS45 and LS47 are coupled to two terminals of the inductor portion LS46, respectively. The inductor portions LS47 and LS49 are coupled to two terminals of the inductor portion LS48, respectively. The inductor portions LG41 and LG43 are coupled to two terminals of the inductor portion LG42, respectively. The inductor portions LG43 and LG45 are coupled to two terminals of the inductor portion LG44, respectively.

Referring to FIG. 4 and FIG. 3A, in some embodiments, the inductors LS1, LS2 and LG are implemented by the input transformer 400. The inductor LS1 is implemented by the inductor portions LS41-LS44 and a part of the inductor portion LS45. The inductor LSS is implemented by the inductor portions LS46-LS49 and another part of the inductor portion LS45. The inductor LG is implemented by the inductor portions LG41-LS45.

In some embodiments, the inductor portion LS41 corresponds to a port of the inductor LS and is coupled to the node N13. The inductor portion LS49 corresponds to a port of the inductor LS and is coupled to the node N12. The inductor portion LS45 corresponds to a center-tapped port of the inductor LS and is coupled to the node N22. The inductor portion LG41 corresponds to a port of the inductor LG and is coupled to the node N16. The inductor portion LG45 corresponds to a port of the inductor LG and is coupled to the node N15.

It is noted that the implementation of the inductors LS1, LS2 and LG are not limited to the configuration shown in FIG. 4. In various embodiments, the inductors LS1, LS2 and LG are implemented by various configurations.

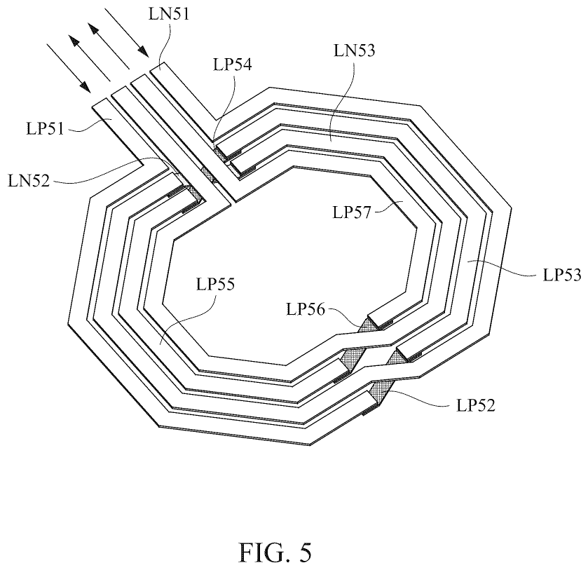

FIG. 5 is a layout diagram of an output transformer 500 corresponding to the inductors LP and LN shown in FIG. 3A, in accordance with some embodiments of the present disclosure. As illustratively shown in FIG. 5, the output transformer 500 includes inductor portions LP51-LP57 and LN51-LN53.

In some embodiments, the inductor portions LP54, LP56 and LP52 are disposed in the same layer which is above the layer of the inductor portion LN52. The inductor portions LP51, LP53, LP55, LP57, LN51 and LN53 are disposed in the same layer which is above the layer of the inductor portions LP54, LP56 and LP52.

As illustratively shown in FIG. 5, the inductor portion LP54 crosses over the inductor portion LN52. The inductor portion LN51 crosses over the inductor portion LP52. The inductor portion LN53 crosses over the inductor portion LP56. Each of the inductor portions LN53 and LP57 crosses over the inductor portion LP54. The output transformer 500 has approximately a round shape. At one side of the round shape, the inductor portions LN51 and LP55 are arranged in order between the inductor portions LP51 and LN53. At another side of the round shape, the inductor portions LN53 and LP53 are arranged in order between the inductor portions LP57 and LN51.

In some embodiments, the inductor portions LP51 and LP53 are coupled to two terminals of the inductor portion LP52, respectively. The inductor portions LP53 and LP55 are coupled to two terminals of the inductor portion LP54, respectively. The inductor portions LP55 and LP57 are coupled to two terminals of the inductor portion LP56, respectively. The inductor portions LN51 and LN53 are coupled to two terminals of the inductor portion LN52, respectively.

Referring to FIG. 5 and FIG. 3A, in some embodiments, the inductors LP and LN are implemented by the input transformer 500. The inductor LP is implemented by the inductor portions LP51-LP57. The inductor LN is implemented by the inductor portions LN51-LN53.

In some embodiments, the inductor portion LP51 corresponds to a port of the inductor LP and is coupled to the node N11. The inductor portion LP57 corresponds to a port of the inductor LP and is coupled to the node N23. The inductor portion LN51 corresponds to a port of the inductor LN and is coupled to the node N24. The inductor portion LN53 corresponds to a port of the inductor LN and is coupled to the node N14.

It is noted that the implementation of the inductors LP and LN are not limited to the configuration shown in FIG. 5. In various embodiments, the inductors LP and LN are implemented by various configurations.

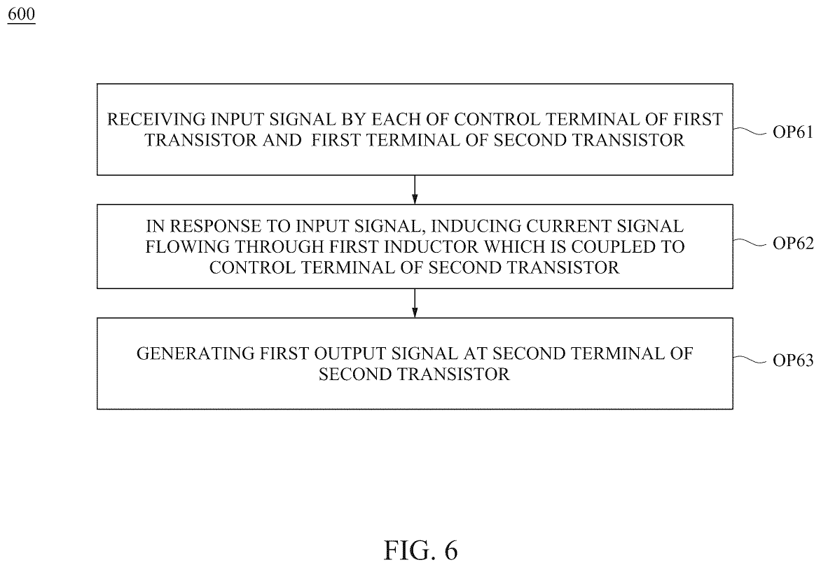

FIG. 6 is a flowchart diagram of a method 600 corresponding to the semiconductor devices 100, 200 and 300 shown in FIG. 1 to FIG. 3A, in accordance with some embodiments of the present disclosure. As illustratively shown in FIG. 6, the method 600 includes operations OP61-OP63.

During the operations OP61, each of the control terminal of the transistor MN1 and a first terminal of the transistor MP1 receives the input signal VIN.

During the operations OP62, in response to the input signal VIN generating the current signal flowing through the inductor LS, the current signal flowing through the inductor LG is induced, in which the inductor LG is coupled to a control terminal of the transistor MP1.

During the operations OP63, the output signal VOP is generated at a second terminal of the transistor MP1.

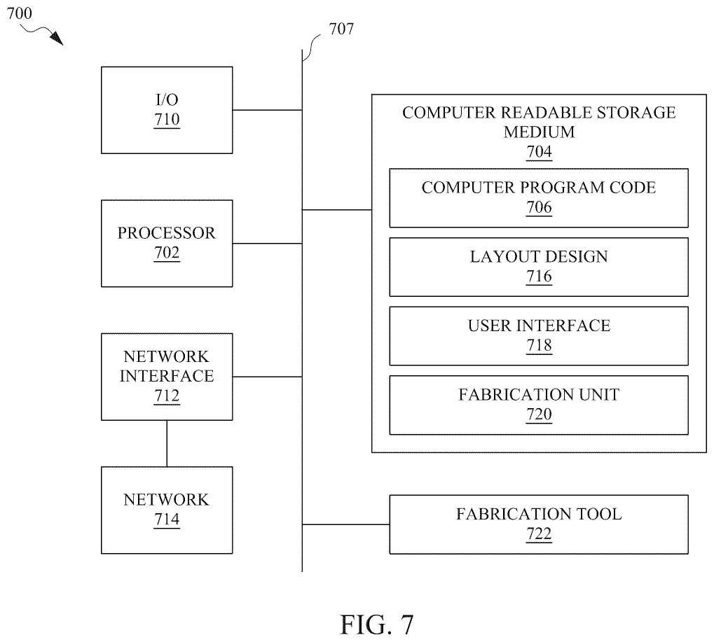

FIG. 7 is a schematic view of a system 700 for designing and/or manufacturing of at least one of the semiconductor devices 100, 200 and 300 shown in FIG. 1 to FIG. 3A, in accordance with some embodiments of the present disclosure. The system 700 generates or places one or more IC layout designs corresponding to at least one of the semiconductor devices 100, 200 and 300, as described herein. In some embodiments, the system 700 manufactures one or more semiconductor devices based on the one or more IC layout designs, as described herein. The system 700 includes a hardware processor 702 and a non-transitory, computer readable storage medium 704 encoded with, e.g., storing, the computer program code 706, e.g., a set of executable instructions. The computer readable storage medium 704 is configured for interfacing with manufacturing machines for producing the semiconductor device. The processor 702 is electrically coupled to the computer readable storage medium 704 by a bus 707. The processor 702 is also electrically coupled to an I/O interface 710 by the bus 707. A network interface 712 is also electrically connected to the processor 702 by the bus 707. Network interface 712 is connected to a network 714, so that the processor 702 and the computer readable storage medium 704 are capable of connecting to external elements via network 714. The processor 702 is configured to execute the computer program code 706 encoded in the computer readable storage medium 704 in order to cause the system 700 designing and/or manufacturing of at least one of the semiconductor devices 100, 200 and 300.

In some embodiments, the processor 702 is a central processing unit (CPU), a multi-processor, a distributed processing system, an application specific integrated circuit (ASIC), and/or a suitable processing unit.

In some embodiments, the computer readable storage medium 704 is an electronic, magnetic, optical, electromagnetic, infrared, and/or a semiconductor system (or apparatus or device). For example, the computer readable storage medium 704 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 704 includes a compact disk-read only memory (CD-ROM), a compact disk-read/write (CD-R/W), and/or a digital video disc (DVD).

In some embodiments, the storage medium 704 also stores information needed for designing and/or manufacturing of at least one of the semiconductor devices 100, 200 and 300, such as layout design 716, user interface 718, fabrication unit 720, and/or a set of executable instructions to designing and/or manufacturing of at least one of the semiconductor devices 100, 200 and 300.

In some embodiments, the storage medium 704 stores instructions (e.g., the computer program code 706) for interfacing with manufacturing machines. The instructions (e.g., the computer program code 706) enable the processor 702 to generate manufacturing instructions readable by the manufacturing machines to effectively implement the semiconductor devices 100, 200 and 300.

The system 700 includes the I/O interface 710. The I/O interface 710 is coupled to external circuitry. In some embodiments, the I/O interface 710 includes a keyboard, keypad, mouse, trackball, trackpad, and/or cursor direction keys for communicating information and commands to the processor 702.

The system 700 also includes the network interface 712 coupled to the processor 702. The network interface 712 allows the system 700 to communicate with the network 714, to which one or more other computer systems are connected. The network interface 712 includes wireless network interfaces such as BLUETOOTH, WIFI, WIMAX, GPRS, or WCDMA; or wired network interface such as ETHERNET, USB, or IEEE-13154. In some embodiments, the designing and/or manufacturing of at least one of the semiconductor devices 100, 200 and 300 is implemented in two or more systems 700, and information such as layout design, user interface and fabrication unit are exchanged between different systems 700 by the network 714.

The system 700 is configured to receive information related to a layout design through the I/O interface 710 or network interface 712. The information is transferred to the processor 702 by the bus 707 to determine a layout design for producing an IC. The layout design is then stored in the computer readable medium 704 as the layout design 716. The system 700 is configured to receive information related to a user interface through the I/O interface 710 or network interface 712. The information is stored in the computer readable medium 704 as the user interface 718. The system 700 is configured to receive information related to a fabrication unit through the I/O interface 710 or network interface 712. The information is stored in the computer readable medium 704 as the fabrication unit 720. In some embodiments, the fabrication unit 720 includes fabrication information utilized by the system 700.

In some embodiments, the designing and/or manufacturing of at least one of the semiconductor devices 100, 200 and 300 is implemented as a standalone software application for execution by a processor. In some embodiments, the designing and/or manufacturing of at least one of the semiconductor devices 100, 200 and 300 is implemented as a software application that is a part of an additional software application. In some embodiments, the designing and/or manufacturing of at least one of the semiconductor devices 100, 200 and 300 is implemented as a plug-in to a software application. In some embodiments, the designing and/or manufacturing of at least one of the semiconductor devices 100, 200 and 300 is implemented as a software application that is a portion of an EDA tool. In some embodiments, the designing and/or manufacturing of at least one of the semiconductor devices 100, 200 and 300 is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, the manufacturing of at least one of the semiconductor devices 100, 200 and 300 is implemented by a manufacturing device to manufacture an integrated circuit using a set of masks manufactured based on one or more layout designs generated by the system 700. In some embodiments, the system 700 includes a manufacturing device (e.g., fabrication tool 722) to manufacture an integrated circuit using a set of masks manufactured based on one or more layout designs of the present disclosure.

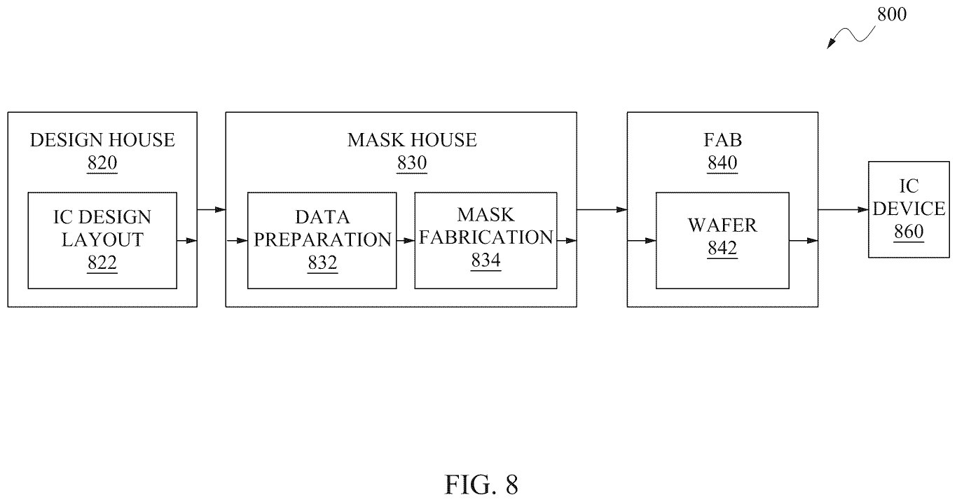

FIG. 8 is a block diagram of an integrated circuit (IC)/semiconductor device manufacturing system 800, and an IC manufacturing flow associated therewith, in accordance with some embodiments of the present disclosure.

In FIG. 8, the IC manufacturing system 800 includes entities, such as a design house 820, a mask house 830, and an IC manufacturer/fabricator (“fab”) 840, that interact with one another in the design, development, and manufacturing cycles and/or services related to manufacturing an IC device (semiconductor device) 860 including at least one of the semiconductor devices 100, 200 and 300. The entities in system 800 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 820, mask house 830, and IC fab 840 is owned by a single company. In some embodiments, two or more of design house 820, mask house 830, and IC fab 840 coexist in a common facility and use common resources.

The design house (or design team) 820 generates an IC design layout 822. The IC design layout 822 includes various geometrical patterns designed for the IC device 860. The geometrical patterns correspond to patterns of metal, oxide, or semiconductor layers that make up the various components of the IC device 860 to be fabricated. The various layers combine to form various IC features. For example, a portion of the IC design layout 822 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 820 implements a proper design procedure to form the IC design layout 822. The design procedure includes one or more of logic design, physical design or place and route. The IC design layout 822 is presented in one or more data files having information of the geometrical patterns. For example, the IC design layout 822 can be expressed in a GDSII file format or DFII file format.

The mask house 830 includes mask data preparation 832 and mask fabrication 834. The mask house 830 uses the IC design layout 822 to manufacture one or more masks to be used for fabricating the various layers of the IC device 860 according to the IC design layout 822. The mask house 830 performs the mask data preparation 832, where the IC design layout 822 is translated into a representative data file (“RDF”). The mask data preparation 832 provides the RDF to the mask fabrication 834. The mask fabrication 834 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 832 to comply with particular characteristics of the mask writer and/or requirements of the IC fab 840. In FIG. 8, the mask data preparation 832 and mask fabrication 834 are illustrated as separate elements. In some embodiments, the mask data preparation 832 and mask fabrication 834 can be collectively referred to as mask data preparation.

In some embodiments, the mask data preparation 832 includes optical proximity correction (OPC) which uses lithography enhancement techniques to compensate for image errors, such as those that can arise from diffraction, interference, other process effects and the like. OPC adjusts the IC design layout 822. In some embodiments, the mask data preparation 832 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 832 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 834, which may undo part of the modifications performed by OPC in order to meet mask creation rules.

In some embodiments, the mask data preparation 832 includes lithography process checking (LPC) that simulates processing that will be implemented by the IC fab 840 to fabricate the IC device 860. LPC simulates this processing based on the IC design layout 822 to create a simulated manufactured device, such as the IC device 860. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 822.

It should be understood that the above description of the mask data preparation 832 has been simplified for the purposes of clarity. In some embodiments, the mask data preparation 832 includes additional features such as a logic operation (LOP) to modify the IC design layout according to manufacturing rules. Additionally, the processes applied to the IC design layout 822 during the mask data preparation 832 may be executed in a variety of different orders.

After the mask data preparation 832 and during mask fabrication 834, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 834 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 840 is an IC fabrication entity that includes one or more manufacturing facilities for the fabrication of a variety of different IC products. In some embodiments, the IC fab 840 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 840 uses the mask (or masks) fabricated by the mask house 830 to fabricate the IC device 860. Thus, the IC fab 840 at least indirectly uses the IC design layout 822 to fabricate the IC device 860. In some embodiments, a semiconductor wafer is fabricated by the IC fab 840 using the mask (or masks) to form the IC device 860. The semiconductor wafer 842 includes a silicon substrate or other proper substrate having material layers formed thereon. Semiconductor wafer further includes one or more of various doped regions, dielectric features, multilevel interconnects, and the like (formed at subsequent manufacturing steps).

Also disclosed is a semiconductor device. The semiconductor device includes a first transistor, a second transistor, a first inductor and a second inductor. A control terminal of the first transistor is configured to receive an input signal. The second transistor is coupled in series with the first transistor, a first terminal of the second transistor being configured to receive the input signal at a first node. The first inductor is coupled between first transistor and the first node. The second inductor is coupled to a control terminal of the second transistor. The first inductor and the second inductor are mutually coupled to each other with transformer coupling.

Also disclosed is a method. The method includes: receiving an input signal by each of a control terminal of a first transistor and a first terminal of a second transistor; in response to the input signal, inducing a current signal flowing through a first inductor which is coupled to a control terminal of the second transistor; and generating a first output signal at a second terminal of the second transistor.

Also disclosed is a semiconductor device. The semiconductor device includes a first transistor, a second transistor, a first inductor and a second inductor. A first terminal of the first inductor is coupled to a first terminal of the first transistor. A first terminal of the second transistor is coupled to a second terminal of the first inductor. The second inductor is coupled to a control terminal of the second transistor. The first inductor and the second inductor are mutually coupled to each other with transformer coupling.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first transistor, a control terminal of the first transistor being configured to receive an input signal;
a second transistor coupled in series with the first transistor, a first terminal of the second transistor being configured to receive the input signal at a first node;
a first inductor coupled between first transistor and the first node; and
a second inductor coupled to a control terminal of the second transistor,
wherein the first inductor and the second inductor are mutually coupled to each other with transformer coupling.

2. The semiconductor device of claim 1, further comprising:
a third inductor and a fourth inductor coupled in series with the first transistor and the second transistor,
wherein the first transistor and the second transistor are coupled between the third inductor and the fourth inductor.

3. The semiconductor device of claim 2, wherein the third inductor and the fourth inductor are mutually coupled to each other with transformer coupling.

4. The semiconductor device of claim 1, further comprising:
a third inductor configured to receive a reference voltage signal,
wherein the second inductor is configured to receive a first bias voltage signal, and
the second transistor is coupled in series between the first inductor and the third inductor.

5. The semiconductor device of claim 4, further comprising:
a third transistor coupled in series between the third inductor and the second transistor, a control terminal of the third transistor being configured to receive a second bias voltage signal.

6. The semiconductor device of claim 4, wherein the first inductor comprises:
a third inductor coupled to the first transistor, and configured to receive the reference voltage signal at a second node; and
a fourth inductor coupled to the second transistor, and configured to receive the reference voltage signal at the second node.

7. The semiconductor device of claim 1, further comprising:
a third inductor configured to receive a reference voltage signal; and
a third transistor coupled in series between the third inductor and the first transistor, a control terminal of the third transistor being configured to receive a first bias voltage signal.

8. A method, comprising:
receiving an input signal by each of a control terminal of a first transistor and a first terminal of a second transistor;
in response to the input signal, inducing a current signal flowing through a first inductor which is coupled to a control terminal of the second transistor; and
generating a first output signal at a second terminal of the second transistor.

9. The method of claim 8, wherein inducing the current signal comprises:
inducing the current signal by a second inductor which is coupled between the first transistor and the second transistor.

10. The method of claim 9, further comprising:
receiving a bias voltage signal and a reference voltage signal by the first inductor and the second inductor, respectively.

11. The method of claim 8, further comprising:
receiving a first bias voltage signal and a first reference voltage signal by a control terminal of a third transistor and a second inductor, respectively,
wherein the second transistor, the second inductor and the third transistor are coupled in series.

12. The method of claim 11, further comprising:
receiving a second bias voltage signal and a second reference voltage signal by a control terminal of a fourth transistor and a third inductor,
wherein the fourth transistor, the third inductor and the fourth transistor are coupled in series, and
the second reference voltage signal is different from the first reference voltage signal.

13. The method of claim 12, wherein the second inductor and the third inductor mutually coupled to each other with transformer coupling.

14. A semiconductor device, comprising:
a first transistor;
a first inductor, a first terminal of the first inductor being coupled to a first terminal of the first transistor;
a second transistor, a first terminal of the second transistor being coupled to a second terminal of the first inductor; and
a second inductor coupled to a control terminal of the second transistor,
wherein the first inductor and the second inductor are mutually coupled to each other with transformer coupling.

15. The semiconductor device of claim 14, wherein the first inductor comprises:
a third inductor coupled to the first transistor, and configured to receive a first reference voltage signal at a first node; and
a fourth inductor coupled to the second transistor, and configured to receive the first reference voltage signal at the first node.

16. The semiconductor device of claim 15, wherein the second inductor is configured to receive a first bias voltage signal.

17. The semiconductor device of claim 15, further comprising:
a fifth inductor coupled in series with the second transistor, and configured to receive the first reference voltage signal.

18. The semiconductor device of claim 17, further comprising:
a sixth inductor coupled in series with the first transistor, and mutually coupled to the fifth inductor with transformer coupling,
wherein the first transistor and the second transistor are coupled between the fifth inductor and the sixth inductor.

19. The semiconductor device of claim 18, further comprising:
a third transistor coupled between the sixth inductor and the first transistor,
wherein a control terminal of the third transistor is configured to receive a first bias voltage signal and the sixth inductor is configured to receive a second reference voltage signal different from the first reference voltage signal.

20. The semiconductor device of claim 19, further comprising:
a fourth transistor coupled between the fifth inductor and the second transistor,
wherein a control terminal of the fourth transistor is configured to receive a second bias voltage signal.
